(19) United States
(12) Patent Application Publication
(10) Pub. No.: US 2023/0093421 A1
(43) Pub. Date: Mar. 23, 2023

(54) THIN FILM TRANSISTOR, MANUFACTURING METHOD THEREFOR, DISPLAY PANEL, AND DISPLAY DEVICE

(71) Applicants: Hefei BOE Display Technology Co., Ltd., Hefei, Anhui (CN); BOE Technology Group Co., Ltd., Beijing (CN)

(72) Inventors: Tao WANG, Beijing (CN); Yinhu HUANG, Beijing (CN); Jincheng GAO, Beijing (CN); Haijiao QIAN, Beijing (CN); Ruifeng ZHANG, Beijing (CN); Dengpan ZHU, Beijing (CN)

(21) Appl. No.: 17/629,019

(22) PCT Filed: Apr. 29, 2021
(86) PCT No.: PCT/CN2021/091194

§ 371 Date: Jan. 21, 2022

(30) Foreign Application Priority Data
May 13, 2020 (CN) 202010401323.7

(51) Int. Cl. H01L 29/49; H01L 27/12; H01L 29/786; H01L 29/40; H01L 29/66

(52) U.S. Cl. CPC H01L 29/4908; H01L 27/1225; H01L 29/7869; H01L 29/401; H01L 29/66969

(57) ABSTRACT

Disclosed in the present application are a thin film transistor, a manufacturing method therefor, a display panel, and a display device. The thin film transistor includes a base substrate, and a metal conductive material, a first silicon-based intermediate layer and a first gate insulating layer sequentially located on the base substrate, where the first silicon-based intermediate layer is bonded to the metal conductive material and the first gate insulating layer by means of chemical bonds.

### CROSS-REFERENCE TO RELATED APPLICATIONS

This application claims the priority of the Chinese patent application No. 202010401323.7 filed to the China Patent Office on May 13, 2020, and entitled “ARRAY SUBSTRATE, MANUFACTURING METHOD THEREFOR, DISPLAY PANEL AND DISPLAY APPARATUS”, of which the entire contents are incorporated herein by reference.

### FIELD

The present application relates to the technical field of display, in particular to a thin film transistor, a manufacturing method therefor, a display panel and a display apparatus.

### BACKGROUND

Existing flat panel display devices mainly include a liquid crystal display (LCD) device and an organic light emitting display (OLED) device. A thin film transistor with an amorphous silicon (a-Si) as an active layer is increasingly unable to meet the requirements of people for high-end products with high resolution, high refresh rate, full screen and the like due to the inherent defect of low electron mobility of the thin film transistor. oxide semiconductors (such as indium gallium zinc oxide (IGZO)) have high electron mobility (about 10 times that of a-Si) and a good on-off ratio; and compared with low temperature poly silicon (LTPS), the oxide semiconductors are simple in manufacturing process and low in cost, and become the most potential active layer material of high-end display products in the future.

However, some problems also exist in the production process of an oxide semiconductor display, IGZO serving as a material of an active layer is very sensitive to hydrogen and water, a silicon oxide (SiOx) material with relatively high water resistance must be adopted as a material of an insulating layer, but the internal stress of the SiOx insulating layer generally shows relatively high negative stress (about −350 Mpa). A Cu thin film serving as an electrode material generally shows positive stress (about 300 Mpa), it can be seen that a large stress difference exists between an electrode and the insulating layer. Additionally, the electrode and the insulating layer are mainly connected through Van der Waals force, the adhesion is poor, and bad bumps often occur between the electrode and the insulating layer in actual production. Besides, the oxide active layer and the insulating layer are generally manufactured at relatively high temperature, while the high temperature enables Cu in the electrode to grow into the insulating layer to form copper whiskers, so that the insulating layer is punctured, the insulating layer is invalid, poor short is formed, and the product yield is seriously influenced.

### SUMMARY

In view of this, embodiments of the present application provide a thin film transistor, a manufacturing method therefor, a display panel and a display apparatus. Specific solutions are as follows.

In a first aspect, a thin film transistor provided by an embodiment of the present application includes: a base substrate, a gate located on the base substrate and made of a metal conductive material, a gate insulating layer located on one side, facing away from the base substrate, of the gate, and a first silicon-based intermediate layer located between the gate and the gate insulating layer;

where the first silicon-based intermediate layer is bonded with the gate and the gate insulating layer through chemical bonds respectively.

Optionally, in the thin film transistor provided by the embodiment of the present application, a material of the gate insulating layer is an inorganic dielectric material containing silicon; and

the first silicon-based intermediate layer is bonded with the gate insulating layer through a “silicon-oxygen-silicon” chemical bond.

In a possible implementation, in the thin film transistor provided by the embodiment of the present application, the first silicon-based intermediate layer is formed after long-chain silane has chemical reactions with the gate and the gate insulating layer in sequence.

Exemplarily, in the thin film transistor provided by the embodiment of the present application, a “silicon-oxygen” bond of the first silicon-based intermediate layer and silicon of the gate insulating layer form the “silicon-oxygen-silicon” chemical bond.

In a possible implementation, the long-chain silane includes one or any combination of 3-aminopropyltrimethoxysilane, 3-mercaptopropyltrimethoxysilane and polycarbosilane.

In a possible implementation, the metal conductive material includes at least one of copper or aluminum; and

a material of the gate insulating layer includes at least one of silicon nitride or silicon oxide.

Exemplarily, in the thin film transistor provided by the embodiment of the present application, the metal conductive material is copper;

when the long-chain silane includes the 3-aminopropyltrimethoxysilane, the first silicon-based intermediate layer is bonded with the gate through a “carboxyl-copper” chemical bond;

when the long-chain silane includes the 3-mercaptopropyltrimethoxysilane, the first silicon-based intermediate layer is bonded with the gate through a “sulfonyl-copper” chemical bond; and

when the long-chain silane includes the polycarbosilane, the first silicon-based intermediate layer is bonded with the gate through a “silicon-oxygen-copper” chemical bond.

In a possible implementation, the thin film transistor further includes: an oxide active layer and a source-drain metal layer sequentially located on one side, facing away from the base substrate, of the gate insulating layer.

In a possible implementation, the thin film transistor further includes a second silicon-based intermediate layer and a passivation layer located on one side, facing away from the oxide active layer, of the source-drain metal layer; where the second silicon-based intermediate layer is located between the source-drain metal layer and the passivation layer; and

the second silicon-based intermediate layer is bonded with the source-drain metal layer and the passivation layer through chemical bonds respectively.

In a possible implementation, a material of the passivation layer is an inorganic dielectric material containing silicon; and

the second silicon-based intermediate layer is bonded with the passivation layer through a “silicon-oxygen-silicon” chemical bond.

In a possible implementation, the second silicon-based intermediate layer is formed after long-chain silane has chemical reactions with the source-drain metal layer and the passivation layer in sequence.

In a second aspect, an embodiment of the present application further provides a manufacturing method of a thin film transistor, including:

providing a base substrate;

forming a metal conductive layer on the base substrate;

placing the base substrate with the metal conductive layer in a solution containing long-chain silane, and modifying a surface of the metal conductive layer with a long-chain silane molecular layer; and

forming an insulating layer on the base substrate modified with the long-chain silane molecular layer, and forming a silicon-based intermediate layer by a reaction of atoms in the long-chain silane molecular layer and the insulating layer in a process of depositing the insulating layer; where the silicon-based intermediate layer is bonded with the metal conductive layer and the insulating layer through chemical bonds respectively.

In a possible implementation, in the manufacturing method provided by the embodiment of the present application, a material of the metal conductive layer includes at least one of copper or aluminum; where the placing the base substrate with the metal conductive layer in the solution containing the long-chain silane, and the modifying the surface of the metal conductive layer with the long-chain silane molecular layer, specifically include:

placing the base substrate with the metal conductive layer in a solution which has a concentration being 5 mg/ml to 15 mg/ml and contains at least one of 3-aminopropyltrimethoxysilane, 3-mercaptopropyltrimethoxysilane and polycarbosilane for a reaction, to modify the surface of the metal conductive layer with the long-chain silane molecular layer.

In a possible implementation, in the manufacturing method provided by the embodiment of the present application, a reaction temperature is controlled to range from 30° C. to 60° C., and reaction time is controlled to range from 10 min to 30 min.

In a possible implementation, in the manufacturing method provided by the embodiment of the present application, a material of the insulating layer is an inorganic dielectric material containing silicon; where the forming the insulating layer on the base substrate modified with the long-chain silane molecular layer, and the forming the silicon-based intermediate layer by the reaction of the atoms in the long-chain silane molecular layer and the insulating layer in the process of depositing the insulating layer, specifically include:

depositing the insulating layer by adopting a plasma enhanced chemical vapor deposition method, and forming the silicon-based intermediate layer by a reaction of silicon atoms in the long-chain silane molecular layer and the insulating layer in the process of depositing the insulating layer; where the silicon-based intermediate layer is bonded with the insulating layer through a “silicon-oxygen-silicon” chemical bond.

In a possible implementation, in the manufacturing method provided by the embodiment of the present application, after forming the metal conductive layer on the base substrate and before placing the base substrate with the metal conductive layer in the solution containing the long-chain silane, the manufacturing method further includes:

cleaning a surface of the metal conductive layer.

In a possible implementation, in the manufacturing method provided by the embodiment of the present application, the cleaning the surface of the metal conductive layer, specifically includes:

removing particles and oil stains on the surface of the metal conductive layer by using air pressure plasma or extreme ultra violet, and then removing an oxide layer on the surface of the metal conductive layer by using a mixed solution of hydrogen peroxide and sulfuric acid.

In a third aspect, an embodiment of the present application further provides a display panel, including the thin film transistor above.

In a fourth aspect, an embodiment of the present application further provides a display apparatus, including the display panel above.

### BRIEF DESCRIPTION OF THE DRAWINGS

FIG. 1 is a schematic structural diagram of a thin film transistor provided by an embodiment of the present application.

FIG. 2 is a schematic structural diagram of another thin film transistor provided by an embodiment of the present application.

FIG. 3 is a flow chart of a manufacturing method of a thin film transistor provided by an embodiment of the present application.

FIG. 4 to FIG. 7 are schematic structural diagrams of a thin film transistor in a manufacturing process provided by embodiments of the present application.

### DETAILED DESCRIPTION OF THE EMBODIMENTS

In order to make the objectives, technical solutions and advantages of the embodiments of the present application more clear, the technical solutions of the embodiments of the present application will be described clearly and completely with reference to the accompanying drawings of the embodiments of the present application. The thickness and the shape of each film layer in the accompanying drawings do not reflect the true scale, and only intend to illustrate the content of the present application. Obviously, the described embodiments are part of the embodiments of the present application, but not all of the embodiments of the present application. On the basis of the described embodiments of the present application, all other embodiments obtained by a person of ordinary skill in the art without inventive efforts fall within the protection scope of the present application.

Unless otherwise defined, the technical or scientific terms used herein shall have the usual meanings understood by the person of ordinary skill in the art to which the present application belongs. The words “first”, “second” and the like used in the specification and claims of the present application do not indicate any order, quantity or importance, but are only used to distinguish different components. Similar words such as “comprise” or “include” mean that elements or objects appearing in front of the word cover elements or objects listed behind the word and their equivalents, without excluding other elements or objects. The “inner”, “outer”, “upper”, “lower” and the like are only used for representing the relative position relation, and when the absolute position of the described object is changed, the relative position relation can also be correspondingly changed.

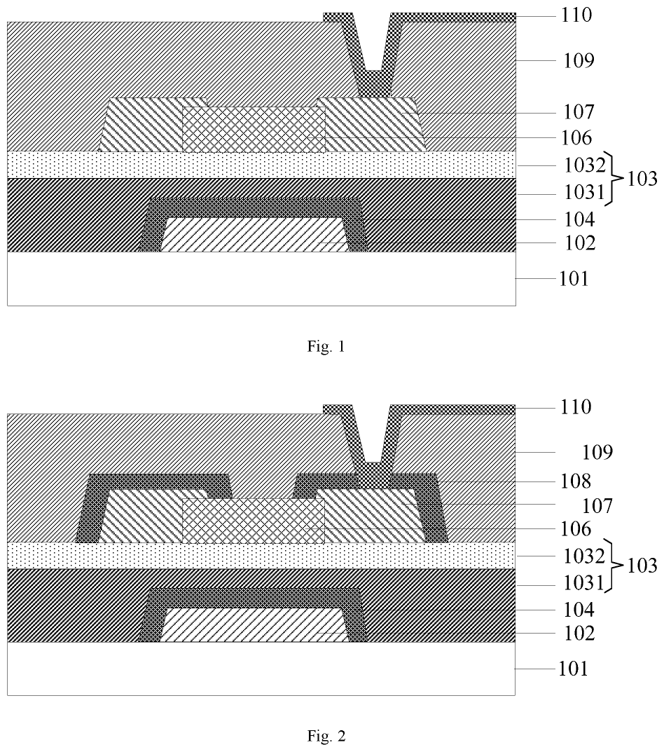

As shown in FIG. 1 and FIG. 2, a thin film transistor provided by an embodiment of the present application includes: a base substrate 101; a gate 102 located on the base substrate 101 and made of a metal conductive material; a gate insulating layer 103 located on one side, facing away from the base substrate 101, of the gate 102; and a first silicon-based intermediate layer 104 located between the gate 102 and the gate insulating layer 103;

where the first silicon-based intermediate layer 104 is bonded with the gate 102 and the gate insulating layer 103 through chemical bonds.

In the thin film transistor provided by the embodiment of the present application, the silicon-based intermediate layer 104 bonded with the gate 102 and the gate insulating layer 103 through the chemical bonds is arranged therebetween, so that an adhesive force between the gate 102 and the gate insulating layer 103 is effectively increased, and the gate 102 and the gate insulating layer 103 are prevented from bulging due to poor adhesion under internal stress of the film layers. In addition, the chemical bond between the silicon-based intermediate layer 104 and the gate 102 can effectively pin atoms in the gate 102, and prevent the diffusion and growth of the gate 102 towards the gate insulating layer 103 in a high-temperature environment in the manufacturing process, so as to improve the product yield.

Optionally, in the thin film transistor provided by the embodiment of the present application, a material of the gate insulating layer is an inorganic dielectric material containing silicon; and the first silicon-based intermediate layer and the gate insulating layer is bonded through a “silicon-oxygen-silicon” chemical bond.

In specific implementation, in the present application, the first silicon-based intermediate layer is formed after a material including long-chain silane has chemical reactions with the gate and the gate insulating layer in sequence. Certainly, the first silicon-based intermediate layer may further include other materials which are known by those skilled in the art and can be bonded with the gate and the gate insulating layer through chemical bonds at the same time, which is not specifically limited here.

Exemplarily, when the first silicon-based intermediate layer is formed after the material including the long-chain silane has the chemical reactions with the gate and the gate insulating layer in sequence, a “silicon-oxygen” bond of the first silicon-based intermediate layer and silicon of the gate insulating layer may form the “silicon-oxygen-silicon” chemical bond, and therefore, the first silicon-based intermediate layer and the gate insulating layer is bonded through the “silicon-oxygen-silicon” chemical bond.

Optionally, in the thin film transistor provided by the embodiment of the present application, the long-chain silane may include: one or any combination of 3-aminopropyltrimethoxysilane (APTMS), 3-mercaptopropyltrimethoxysilane (MPTMS) and polycarbosilane (DSCBOS).

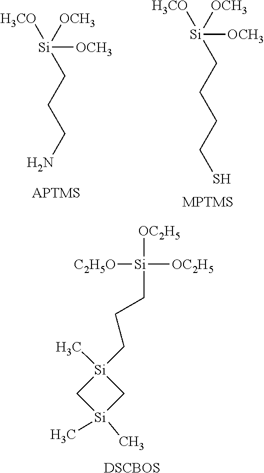

In specific implementation, a material of the metal conductive material includes at least one of copper or aluminum; and a material of the gate insulating layer includes at least one of silicon nitride or silicon oxide.

Specifically, in the case where the first silicon-based intermediate layer 104 is formed from the 3-aminopropyltrimethoxysilane, the gate 102 is formed from the copper, and the gate insulating layer 103 is formed from the inorganic dielectric material containing silicon: a mixed solution of the 3-aminopropyltrimethoxysilane and succinyl chloride has a hydrolysis reaction to generate a carboxyl functional group, as shown in the following equation:

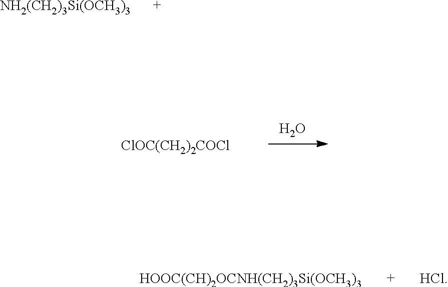

The carboxyl functional group reacts with the copper to generate a carboxyl copper complex, so that the first silicon-based intermediate layer 104 and the gate 102 are bonded through the “carboxyl-copper” chemical bond. Besides, in the process of manufacturing the gate insulating layer 103 by adopting a plasma enhanced chemical vapor deposition (PECVD) method, in a plasma environment, methyl group (—CH3) of the 3-aminopropyltrimethoxysilane falls off, and a suspended oxygen bond reacts with a silyl radical in the environment to generate the “silicon-oxygen-silicon (Si—O—Si)” chemical bond, so that the first silicon-based intermediate layer 104 and the gate insulating layer 103 are bonded through the “silicon-oxygen-silicon” chemical bond.

In the case where the first silicon-based intermediate layer 104 is formed from the 3-mercaptopropyltrimethoxysilane, the gate 102 is formed from the copper, and the gate insulating layer 103 is formed from the inorganic dielectric material containing silicon: a sulfhydryl group (—SH) in the 3-mercaptopropyltrimethoxysilane is oxidized into a sulfonyl group (—SO₃) under the action of UV, and the sulfonyl group reacts with the copper to generate a copper sulfonate complex, so that the first silicon-based intermediate layer 104 and the gate 102 are bonded through the “sulfonyl-copper” chemical bond. Besides, in a plasma environment, methyl group (—CH₃) of the 3-mercaptopropyltrimethoxysilane falls off, and a suspended oxygen bond reacts with a silyl radical in the environment to generate the “silicon-oxygen-silicon (Si—O—Si)” chemical bond, so that the first silicon-based intermediate layer 104 and the gate insulating layer 103 are bonded through the “silicon-oxygen-silicon” chemical bond.

In the case where the first silicon-based intermediate layer 104 is formed from the polycarbosilane, the gate 102 is formed from the copper, and the gate insulating layer 103 is formed from the inorganic dielectric material containing silicon: when the polycarbosilane acts on the surface of the copper, a silicon ring cracks, and silicon is bonded with oxygen in the air to generate a silicon-oxygen bond. Oxygen atoms in the silicon-oxygen bond further act with the copper to generate a “silicon-oxygen-copper” chemical bond, so that the first silicon-based intermediate layer 104 and the gate 102 are bonded through the “silicon-oxygen-copper” chemical bond. Besides, in a plasma environment, ethyl group (—C₂H₅) of the polycarbosilane falls off, and a suspended oxygen bond reacts with a silyl radical in the environment to generate the “silicon-oxygen-silicon (Si—O—Si)” chemical bond, so that the first silicon-based intermediate layer 104 and the gate insulating layer 103 are bonded through the “silicon-oxygen-silicon” chemical bond.

Optionally, in the thin film transistor provided by the embodiment of the present application, as shown in FIG. 1, the thin film transistor further includes: an oxide active layer 106 and a source-drain metal layer 107 sequentially located on one side, facing away from the base substrate 101, of the gate insulating layer 103. The gate insulating layer 103 may include a first gate insulating layer 1031 made of silicon nitride, and generally, the gate insulating layer may further include a second gate insulating layer 1032 made of silicon oxide, which is not limited here.

The first gate insulating layer 1031 and the second gate insulating layer 1032 which are arranged in a laminated mode may effectively prevent water and hydrogen from invading the oxide active layer 106, so that the performance of the transistor is improved. In the present application, the first silicon-based intermediate layer 104 has a hydrophobic long chain, can effectively block the water and the hydrogen, prevents the water and the hydrogen from invading the oxide active layer 106 to cause failure of the transistor characteristic, and improves the product stability.

Besides, in the related technology, in order to guarantee the stability of the transistor with the oxide active layer 106, an annealing temperature higher than that of an amorphous silicon semiconductor (generally 350° C. or above) will be used, the high temperature enables the material (such as Cu) of the gate 102 to grow into the gate insulating layer 103 to form copper whiskers, and under the follow-up plasma environment or the electrostatic effect, the growing and diffusing the copper whiskers of the gate 102 break down the gate insulating layer 103 very easily, so that the insulating effect is invalid, and the poor short between the gate 102 and the source-drain metal layer 107 is caused. In the thin film transistor provided by the present application, the silicon-based intermediate layer 104 bonded with the gate 102 through the chemical bond may play an effective pinning role on copper atoms of the gate 102, so that insulation failure caused by diffusion and growth of the gate 102 towards the gate insulating layer 103 in a high-temperature environment in a manufacturing process is avoided, thereby effectively preventing poor short between the gate 102 and the source-drain metal layer 107, and improving the product yield.

Optionally, in the thin film transistor provided by the embodiment of the present application, as shown in FIG. 2, the thin film transistor further includes a second silicon-based intermediate layer 108 and a passivation layer 109 located on one side, facing away from the oxide active layer 106, of the source-drain metal layer 107. The second silicon-based intermediate layer 108 is located between the source-drain metal layer 107 and the passivation layer 109. The second silicon-based intermediate layer 108 is bonded with the source-drain metal layer 107 and the passivation layer 109 through chemical bonds respectively.

Further, as shown in FIG. 2, the thin film transistor may further include: a pixel electrode layer 110 located on one side, facing away from the base substrate 101, of the passivation layer 109. In other words, the second silicon-based intermediate layer 108 bonded through the chemical bond is arranged between the source-drain metal layer 107 and the passivation layer 109, so that the adhesive force between the source-drain metal layer 107 and the passivation layer 109 is effectively improved, diffusion of metal (such as Cu) of the source-drain metal layer 107 can be prevented, and poor short between the source-drain metal layer 107 and the pixel electrode layer 110 is avoided.

Optionally, in the thin film transistor provided by the embodiment of the present application, a material of the passivation layer is an inorganic dielectric material containing silicon; and the second silicon-based intermediate layer and the passivation layer are bonded through a “silicon-oxygen-silicon” chemical bond.

In specific implementation, in the present application, the second silicon-based intermediate layer is formed after a material including long-chain silane has chemical reactions with the source-drain metal layer and the passivation layer in sequence. Certainly, the second silicon-based intermediate layer may further include other materials which are known by those skilled in the art and can be bonded with the source-drain metal layer and the passivation layer through chemical bonds at the same time, which is not specifically limited here.

Exemplarily, when the second silicon-based intermediate layer is formed after the material including the long-chain silane has the chemical reactions with the source-drain metal layer and the passivation layer in sequence, a “silicon-oxygen” bond of the second silicon-based intermediate layer and silicon of the passivation layer form the “silicon-oxygen-silicon” chemical bond, and therefore, the second silicon-based intermediate layer and the passivation layer are bonded through the “silicon-oxygen-silicon” chemical bond.

In specific implementation, the arrangement of the second silicon-based intermediate layer may refer to the first silicon-based intermediate layer, and bonding of the second silicon-based intermediate layer and the source-drain metal layer may refer to bonding of the first silicon-based intermediate layer and the gate, which are not described in details here.

Based on the same technical concept, an embodiment of the present application provides a manufacturing method of a thin film transistor. The principle of solving the problem of the manufacturing method is similar to the principle of solving the problem of the thin film transistor above, so that implementation of the manufacturing method provided by the embodiment of the present application may refer to the implementation of the thin film transistor provided by the embodiment of the present application, and repetitions are omitted.

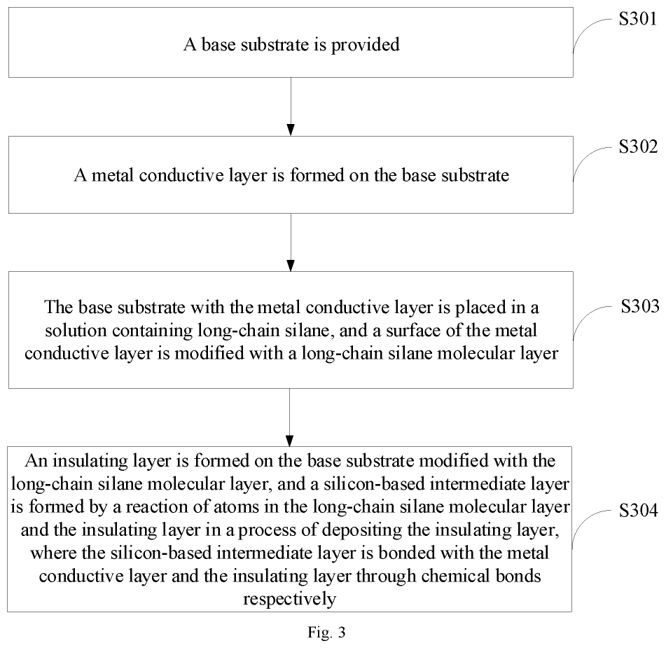

Specifically, as shown in FIG. 3, the manufacturing method of the thin film transistor further provided by the embodiment of the present application may specifically include the following steps.

S301, a base substrate is provided.

S302, a metal conductive layer is formed on the base substrate.

S303, the base substrate with the metal conductive layer is placed in a solution containing long-chain silane, and a surface of the metal conductive layer is modified with a long-chain silane molecular layer.

S304, an insulating layer is formed on the base substrate modified with the long-chain silane molecular layer, and a silicon-based intermediate layer is formed by a reaction of atoms in the long-chain silane molecular layer and the insulating layer in a process of depositing the insulating layer, where the silicon-based intermediate layer is bonded with the metal conductive layer and the insulating layer through chemical bonds respectively.

Optionally, in the manufacturing method provided by the embodiment of the present application, a material of the metal conductive layer includes at least one of copper or aluminum; and the placing the base substrate with the metal conductive layer in the solution containing the long-chain silane, and the modifying the surface of the metal conductive layer with the long-chain silane molecular layer, specifically include:

placing the base substrate with the metal conductive layer in a solution which has a concentration being 5 mg/ml to 15 mg/ml (for example, 5 mg/ml, 8 mg/ml, 10 mg/ml, 13 mg/ml, and 15 mg/ml) and contains at least one of 3-aminopropyltrimethoxysilane, 3-mercaptopropyltrimethoxysilane and polycarbosilane for a reaction, to modify the surface of the metal conductive layer with the long-chain silane molecular layer.

A reaction temperature may be controlled between 30° C. and 60° C., such as 30° C., 35° C., 40° C., 45° C., 50° C., 55° C., and 60° C., which is not limited here. Reaction time is controlled between 10 min and 30 min, such as 10 min, 15 min, 20 min, 25 min, and 30 min, which is not limited here.

Optionally, a solvent of the solution containing the long-chain silane may be ethyl alcohol or methylbenzene or the like; and when the solution containing the long-chain silane is a mixed solution of the 3-aminopropyltrimethoxysilane, the 3-mercaptopropyltrimethoxysilane and the polycarbosilane, the proportions of all the components may be flexibly combined according to actual needs, and it is guaranteed that the total concentration ranges from 5 mg/ml to 15 mg/ml.

In order to better understand the technical solution of step S303, detailed illustration is made below by taking an example that the solution containing the long-chain silane is a solution containing the 3-aminopropyltrimethoxysilane and the metal conductive layer is made of copper metal.

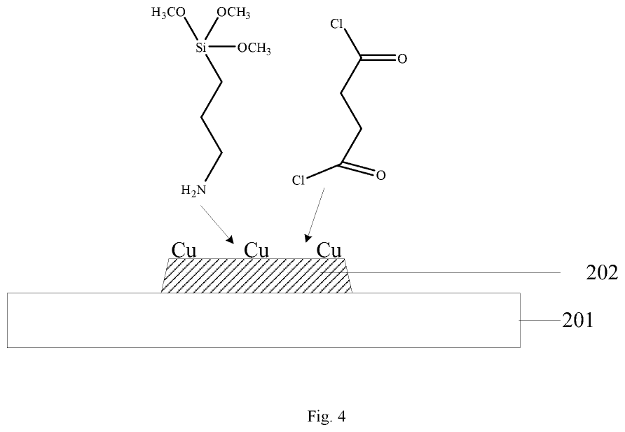

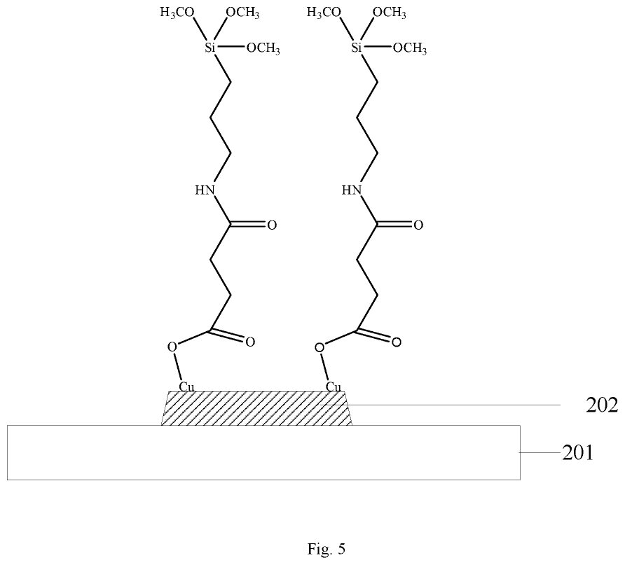

A base substrate 201 with a metal conductive layer 202 is placed into a mixed organic solution which has a concentration being 5 mg/ml to 15 mg/ml and contains the 3-aminopropyltrimethoxysilane and succinyl chloride (as shown in FIG. 4), and silylation treatment is carried out for 10 min to 30 min under the condition of 30° C. to 60° C., so as to make the mixed solution of the 3-aminopropyltrimethoxysilane and the succinyl chloride have a hydrolysis reaction to generate a carboxyl functional group. One end of carboxylated 3-aminopropyltrimethoxysilane is hydrophilic, and the other end thereof is hydrophobic. Hydrophilic carboxyl and the copper metal generate a carboxyl copper complex, diffusion motion of the metal copper may be effectively prevented, the carboxyl copper complex has strong bonding force with the metal copper, and the hydrophobic end points to the outer side as shown in FIG. 5.

Optionally, in the manufacturing method provided by the embodiment of the present application, a material of the insulating layer is an inorganic dielectric material containing silicon; and step S304 that the insulating layer is formed on the base substrate modified with the long-chain silane molecular layer, and the silicon-based intermediate layer is formed by the reaction of the atoms in the long-chain silane molecular layer and the insulating layer in the process of depositing the insulating layer, may be specifically implemented through the following way:

the insulating layer is deposited by adopting a plasma enhanced chemical vapor deposition method, and the silicon-based intermediate layer is formed by a reaction of silicon atoms in the long-chain silane molecular layer and the insulating layer in the process of depositing the insulating layer; where the silicon-based intermediate layer is bonded with the insulating layer through a “silicon-oxygen-silicon” chemical bond.

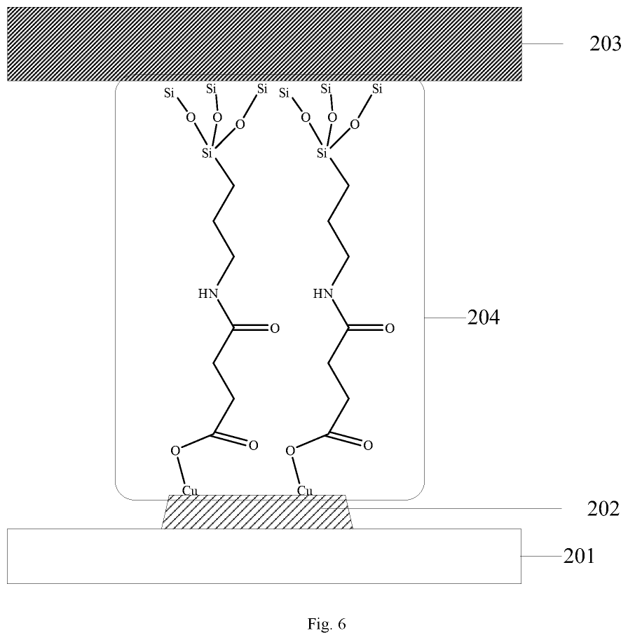

Specifically, as shown in FIG. 6, in a plasma environment, a C—O bond in —Si(OCH₃)₃ at one end of a silicon-based hydrophobic layer on a surface of the metal conductive layer 202 is broken, methyl group falls off, and a suspended oxygen bond reacts with a silyl radical in the environment to generate a Si—O—Si chemical bond, so that one end of a silicon-based intermediate layer 204 and the metal conductive layer 202 generate a carboxyl copper complex, and the other end of the silicon-based intermediate layer 204 and an insulating layer 203 form a Si—O—Si chemical bond, to play a role of an intermediate bridge, so as to increase the adhesive force between the metal conductive layer 202 and the insulating layer 203.

As described above, preparation of the silicon-based intermediate layer 204 does not require an additional patterning operation and thus does not require an increase in mask cost. In addition, a silylation reaction apparatus may be directly transformed on the basis of an existing wet etching device so that a production line can be quickly upgraded.

Optionally, in the manufacturing method provided by the embodiment of the present application, after executing step S302 that the metal conductive layer is formed on the base substrate, and before executing step S303 that the base substrate with the metal conductive layer is placed in the solution containing the long-chain silane to make the metal conductive layer react with the solution containing the long-chain silane, the following step may further be executed:

a surface of the metal conductive layer is cleaned to remove impurities such as particles, oil stains and oxides on the surface of the metal conductive layer, so that manufacturing of the silicon-based intermediate layer subsequently through a silylation manner is facilitated.

Optionally, in the manufacturing method provided by the embodiment of the present application, cleaning the surface of the metal conductive layer may be specifically implemented through the following way.

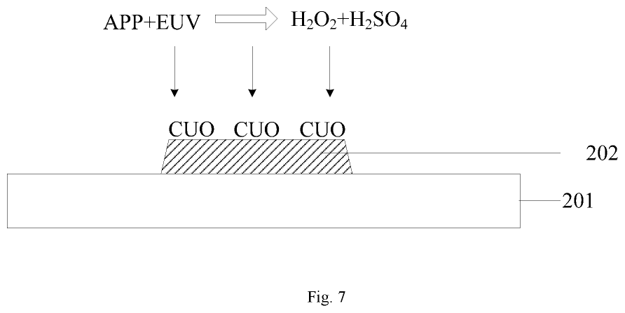

As shown in FIG. 7, first, particles and oil stains on the surface of the metal conductive layer 202 are removed by using air pressure plasma (APP) or extreme ultra violet (EUV) and the like; and then a mixed solution of hydrogen peroxide (H₂O₂) and sulfuric acid (H₂SO₄) is used for removing an oxide layer (such as CuO) on the surface of the metal conductive layer 202. Specifically, a concentration of the hydrogen peroxide is 5%, a concentration of the sulfuric acid is 10%, and treatment time is 30 s.

It can be understood that the preparation method provided by the embodiment of the present application can be used for preparing the gate of the thin film transistor and can also be used for preparing the source-drain metal layer of the thin film transistor. When the method is used for preparing the gate of the thin film transistor, the metal conductive layer formed in step S302 may be the gate 102 as shown in FIG. 1 and FIG. 2, the insulating layer formed in step S304 may be the gate insulating layer 103 as shown in FIG. 1 and FIG. 2, and the silicon-based intermediate layer formed in step S304 may be the first silicon-based intermediate layer 104 as shown in FIG. 1 and FIG. 2. When the method is used for preparing the source-drain metal layer of the thin film transistor, the metal conductive layer formed in step S302 may be the source-drain metal layer 107 as shown in FIG. 2, the insulating layer formed in step S304 may be the passivation layer 109 as shown in FIG. 2, and the silicon-based intermediate layer formed in step S304 may be the second silicon-based intermediate layer 108 as shown in FIG. 2.

Based on the same technical concept, an embodiment of the present application further provides a display panel which includes the thin film transistor provided by the embodiments of the present application. The display panel may be: a LCD, an OLED, a light emitting diode (LED) panel, a quantum dot light emitting diode (QLED) panel, a micro light emitting diode (Micro LED) panel, a mini light emitting diode (Mini LED) panel and the like. Other essential components of the display panel should be understood by those of ordinary skill in the art, and will not be repeated here, nor should they be regarded as a limitation of the present application. In addition, since the principle of solving the problem of the display panel is similar to that of the thin film transistor, the implementation of the display panel may refer to the embodiment of the thin film transistor, and repetitions are omitted.

Based on the same technical concept, an embodiment of the present application further provides a display apparatus which includes the display panel provided by the embodiment of the present application. The display apparatus may be: any product or part with a display function, such as a mobile phone, a tablet computer, a television, a display, a notebook computer, a digital photo frame, a navigator, a smart watch, a fitness wrist strap, and a personal digital assistant. Other essential components of the display apparatus should be understood by those of ordinary skill in the art, and will not be repeated here, nor should they be regarded as a limitation of the present application. In addition, since the principle of solving the problem of the display apparatus is similar to that of the display panel, the implementation of the display apparatus may refer to the embodiment of the display panel, and repetitions are omitted.

According to the thin film transistor, the manufacturing method therefor, the display panel and the display apparatus provided by the embodiments of the present application, the thin film transistor includes the base substrate, the gate located on the base substrate and made of the metal conductive material, the gate insulating layer located on one side, facing away from the base substrate, of the gate, and the first silicon-based intermediate layer located between the gate and the gate insulating layer; where the first silicon-based intermediate layer is bonded with the gate and the gate insulating layer through the chemical bonds. The silicon-based intermediate layer bonded with the gate and the gate insulating layer through the chemical bonds are arranged therebetween, so that the adhesive force between the gate and the gate insulating layer is effectively increased, and the gate and the gate insulating layer are prevented from bulging due to poor adhesion under internal stress of the film layers. In addition, the chemical bonds between the silicon-based intermediate layer and the gate can effectively pin the atoms in the gate, and prevent the diffusion and growth of the gate towards the gate insulating layer in the high-temperature environment in the manufacturing process, thus improving the product yield.

Obviously, those skilled in the art can make various modifications and variations to the present application without departing from the spirit and scope of the present application. Thus, if these modifications and variations of the present application fall within the scope of the claims of the present application and the equivalent art, the present application is also intended to include these modifications and variations.

1. A thin film transistor, comprising:
a base substrate;
a gate arranged on the base substrate and made of a metal conductive material;
a gate insulating layer arranged on one side, facing away from the base substrate, of the gate, and
a first silicon-based intermediate layer arranged between the gate and the gate insulating layer;
wherein the first silicon-based intermediate layer is bonded with the gate and the gate insulating layer through chemical bonds respectively.

2. The thin film transistor according to claim 1, wherein a material of the gate insulating layer is an inorganic dielectric material comprising silicon; and
the first silicon-based intermediate layer is bonded with the gate insulating layer through a “silicon-oxygen-silicon” chemical bond.

3. The thin film transistor according to claim 2, wherein the first silicon-based intermediate layer is formed after long-chain silane has chemical reactions with the gate and the gate insulating layer in sequence.

4. The thin film transistor according to claim 3, wherein a “silicon-oxygen” bond of the first silicon-based intermediate layer and the silicon of the gate insulating layer form the “silicon-oxygen-silicon” chemical bond.

5. The thin film transistor according to claim 3, wherein the long-chain silane comprises one or any combination of 3-aminopropyltrimethoxysilane, 3-mercaptopropyltrimethoxysilane and polycarbosilane.

6. The thin film transistor according to claim 5, wherein the metal conductive material comprises at least one of copper or aluminum; and
the material of the gate insulating layer comprises at least one of silicon nitride or silicon oxide.

7. The thin film transistor according to claim 6, wherein the metal conductive material is the copper;
when the long-chain silane comprises the 3-aminopropyltrimethoxysilane, the first silicon-based intermediate layer is bonded with the gate through a “carboxyl-copper” chemical bond;
when the long-chain silane comprises the 3-mercaptopropyltrimethoxysilane, the first silicon-based intermediate layer is bonded with the gate through a “sulfonyl-copper” chemical bond; and
when the long-chain silane comprises the polycarbosilane, the first silicon-based intermediate layer is bonded with the gate through a “silicon-oxygen-copper” chemical bond.

8. The thin film transistor according to claim 1, wherein the thin film transistor further comprises: an oxide active layer and a source-drain metal layer sequentially arranged on one side, facing away from the base substrate, of the gate insulating layer.

9. The thin film transistor according to claim 8, further comprising a second silicon-based intermediate layer and a passivation layer arranged on one side, facing away from the oxide active layer, of the source-drain metal layer;
wherein the second silicon-based intermediate layer is arranged between the source-drain metal layer and the passivation layer; and
the second silicon-based intermediate layer is bonded with the source-drain metal layer and the passivation layer through chemical bonds respectively.

10. The thin film transistor according to claim 9, wherein a material of the passivation layer is an inorganic dielectric material comprising silicon; and
the second silicon-based intermediate layer is bonded with the passivation layer through a “silicon-oxygen-silicon” chemical bond.

11. The thin film transistor according to claim 10, wherein the second silicon-based intermediate layer is formed after long-chain silane has chemical reactions with the source-drain metal layer and the passivation layer in sequence.

12. A manufacturing method of a thin film transistor, comprising:
providing a base substrate;
forming a metal conductive layer on the base substrate;
placing the base substrate with the metal conductive layer in a solution comprising long-chain silane, and modifying a surface of the metal conductive layer with a long-chain silane molecular layer; and
forming an insulating layer on the base substrate modified with the long-chain silane molecular layer, and forming a silicon-based intermediate layer by a reaction of atoms in the long-chain silane molecular layer and the insulating layer in a process of depositing the insulating layer; wherein the silicon-based intermediate layer is bonded with the metal conductive layer and the insulating layer through chemical bonds respectively.

13. The manufacturing method according to claim 12, wherein a material of the metal conductive layer comprises at least one of copper or aluminum;
wherein the placing the base substrate with the metal conductive layer in the solution comprising the long-chain silane, and the modifying the surface of the metal conductive layer with the long-chain silane molecular layer, specifically comprise:
placing the base substrate with the metal conductive layer in a solution which has a concentration being 5 mg/ml to 15 mg/ml and comprises at least one of 3-aminopropyltrimethoxysilane, 3-mercaptopropyltrimethoxysilane and polycarbosilane for a reaction, to modify the surface of the metal conductive layer with the long-chain silane molecular layer.

14. The manufacturing method according to claim 13, wherein a reaction temperature is controlled to range from 30 [symbol] to 60 [symbol] , and reaction time is controlled to range from 10 min to 30 min.

15. The manufacturing method according to claim 12, wherein a material of the insulating layer is an inorganic dielectric material comprising silicon;
wherein the forming the insulating layer on the base substrate modified with the long-chain silane molecular layer, and the forming the silicon-based intermediate layer by the reaction of the atoms in the long-chain silane molecular layer and the insulating layer in the process of depositing the insulating layer, specifically comprise:
depositing the insulating layer by adopting a plasma enhanced chemical vapor deposition method, and forming the silicon-based intermediate layer by a reaction of silicon atoms in the long-chain silane molecular layer and the insulating layer in the process of depositing the insulating layer;
wherein the silicon-based intermediate layer is bonded with the insulating layer through a “silicon-oxygen-silicon” chemical bond.

16. The manufacturing method of claim 12, wherein after forming the metal conductive layer on the base substrate and before placing the base substrate with the metal conductive layer in the solution comprising the long-chain silane, the manufacturing method further comprises:
cleaning a surface of the metal conductive layer.

17. The manufacturing method according to claim 16, wherein the cleaning the surface of the metal conductive layer, specifically comprises:
removing particles and oil stains on the surface of the metal conductive layer by using air pressure plasma or extreme ultra violet, and then removing an oxide layer on the surface of the metal conductive layer by using a mixed solution of hydrogen peroxide and sulfuric acid.

18. A display panel, comprising the thin film transistor according to claim 1.

19. A display apparatus, comprising the display panel according to claim 18.
